(19) United States
(12) Patent Application Publication
(10) Pub. No.: US 2014/0196771 A1
(43) Pub. Date: Jul. 17, 2014

(54) THIN-FILM PHOTOVOLTAIC MODULE WITH HYDROPHOBIC REAR-SIDE COATING

(71) Applicants: Stephane Auvray, Suresnes (FR); Dana Pakosch, Muenchen (DE); Dang Cuong Phan, Aachen (DE)

(72) Inventors: Stephane Auvray, Suresnes (FR); Dana Pakosch, Muenchen (DE); Dang Cuong Phan, Aachen (DE)

(21) Appl. No.: 14/232,878

(22) PCT Filed: Jul. 5, 2012
(86) PCT No.: PCT/EP2012/063104

§ 371 Date: Mar. 20, 2014

(30) Foreign Application Priority Data
Aug. 29, 2011 (EP) 11179157.0

(51) Int. Cl. H01L 31/048; H01L 31/0216

(52) U.S. Cl. CPC H01L 31/048; H01L 31/02167
USPC 136/251; 438/64

(57) ABSTRACT

A thin-film photovoltaic module with hydrophobic rear-side coating is described. The module has a substrate, wherein at least one hydrophobic coating is arranged on a rear side of the substrate, a photovoltaic layer structure on a front side of the substrate, and a covering sheet, which is areally connected to the front side of the substrate via a rear side of the substrate with at least one intermediate layer.

The invention relates to a thin-film photovoltaic module with hydrophobic rear-side coating, a method for its production, and its use.

Thin-film photovoltaic modules are exposed, for example, in open areas or roof systems at high electrical voltages, to severe weathering. Thin-film photovoltaic modules customarily contain monolithically integrated thin-film photovoltaic cells that corrode in the presence of moisture in the photovoltaic modules.

It is known that due to different electrical potentials between the ground potential of the immediate surroundings of the thin-film photovoltaic module and the photovoltaic layer structure, a high electrical system voltage of as much as 1000 V develops. The surroundings at ground potential can, for example, be represented by grounded mounting means of the thin-film photovoltaic module or by a conductive film of water with a ground connection on the thin-film photovoltaic module. The high system voltage results in high electrical field strengths between the module frame and the photovoltaic layer structure. Electrical transients can arise from this or ions can drift out of the glass into the thin layers of the photovoltaic cells. Corrosion or delamination of the photovoltaic cells results in permanent degradation of the performance or in the failure of the photovoltaic modules.

To feed electrical energy into the public supply network, photovoltaic systems require a circuit of photovoltaic modules and inverters to convert DC voltage into AC voltage.

From DE 10 2007 050 554 A1, photovoltaic systems with a rise in potential to reduce the degradation of performance during long-term use are known. The potential of the positive terminal of the circuit of photovoltaic modules is shifted in the inverter relative to the ground potential such that no uncontrolled electrical discharges from the photovoltaic module to ground occur.

Also known are inverters for photovoltaic systems that isolate the photovoltaic modules galvanically from the potential to the ground via an isolating transformer to prevent uncontrolled discharges from the photovoltaic system to the ground. However, that requires costly use of inverters adapted to the photovoltaic modules, which inverters have low electrical efficiency.

DE 10 2009 044 142 A1 discloses a thin-film component on glass with an electrically conductive protection device. The drift of ions from the glass pane and/or electrical discharges caused by an electrical field is shifted from the functional layer or structure to the electrically conductive protection device. The introduction of the electrically conductive protection device as an additional electrical component renders the production process of the thin-film component more difficult.

DE 10 2008 007 640 A1 discloses a photovoltaic module with a hydrophobic coating of the light-incident side (cover sheet). This prevents wetting of the light entry side with moisture. Precipitation that strikes drips off the cover sheet and the deposition of dirt particles carried along in the precipitation is reduced. This is intended to reduce degradation of the efficiency of the photovoltaic module as result of soiling of the cover sheet.

Glass panes with hydrophobic coatings that are provided as cover sheets of photovoltaic modules facing the entry of light are also known from DE 100 63 739 A1, US 2002/0014090 A1, and US 2010/0119774 A1.

The object of the present invention is to provide an improved thin-film photovoltaic module that is protected against moisture and high electric field strengths independently of an inverter and additional electrical components.

The object of the present invention is accomplished according to the invention by a thin-film photovoltaic module with hydrophobic rear-side coating according to the independent claim 1. Preferred embodiments emerge from the subclaims.

The thin-film photovoltaic module with hydrophobic rear-side coating according to the invention comprises the following characteristics:
a substrate, wherein at least one hydrophobic coating is arranged on the rear side of the substrate,
a photovoltaic layer structure on the front side of the substrate, and
a cover sheet that is areally bonded via its rear side with at least one intermediate layer to the front side of the substrate.

In the context of the invention, “front side” means the side facing the incidence of light. “Rear side” means the side turned away from the incidence of light.

The thin-film photovoltaic module according to the invention comprises a photovoltaic module in the substrate configuration. The photovoltaic layer structure is deposited directly onto the substrate. The substrate is situated on the side of the photovoltaic module turned away from the incidence of light. The cover sheet faces the incidence of light. The incidence of light into the photovoltaic module takes place via the cover sheet.

The strength of the electrical field between the grounded module frame and the photovoltaic layer structure is decisively dependent on the electrical surface conductivity of the substrate on which the photovoltaic layer structure is arranged. It has been demonstrated in computer simulations on photovoltaic test cells with a difference in potential between the module frame and the photovoltaic layer structure of 1000 V that, for example, an increase of the surface conductivity of the glass substrate from 8.3×10⁻¹⁴ S/m (fresh glass) to 3.3×10⁻⁸ S/m (aged glass) results in an increase in the electrical field strength by 16% from 630000 V/m to 730000 V/m.

The electrical surface conductivity of the substrate is particularly high when, as a result of precipitation or due to condensed atmospheric moisture, a continuous film of water forms on the surface of the substrate. The contact angle for water on the surface of the substrate is enlarged by the hydrophobic coating according to the invention. This reduces the wetting of the surface of the substrate with water and, in particular, advantageously prevents the formation of a complete film of water on the surface of substrate turned away from the layer structure applied thereon. This reduces the strength of the electrical field between the module frame and the photovoltaic layer structure. This yields a reduced risk of electrical discharge from the photovoltaic system to ground. Moreover, the drifting of ions out of the substrate into the thin films of the photovoltaic cells is reduced. The particular advantage resides in a reduced corrosion of the photovoltaic layer structure and, thus, in a reduced degradation of performance of the thin-film photovoltaic module in long-term use. The hydrophobic coating according to the invention also advantageously reduces the risk of the penetration of moisture into the photovoltaic module.

The hydrophobic coating preferably contains at least one organosilane. In that case, the silicon atom is substituted with at least one organic group.

In a preferred embodiment of the invention, the organic group is an alkyl group. The structure of the alkyl group can be linear, branched, or cyclic. The alkyl group preferably has from 2 to 21 carbon atoms, particularly preferably from 8 to 16 carbon atoms. This is particularly advantageous with regard to the hydrophobic properties of the coating and the reactivity of the alkylsilane at the time of application of the coating.

The alkyl group is particularly preferably halogenated, most particularly preferably fluorinated. In particular, the alkyl chain includes at least one perfluorinated alkyl group on the chain end away from the silicon atom or, in the case of a branched alkyl chain, on the chain end away from the silicon atom. “Perfluorinated” means that the alkyl group is completely substituted with fluorine atoms. This is particularly advantageous with regard to the hydrophobic properties and the chemical resistance of the coating.

Alternatively, the organic group can contain a polyether group, preferably a halogenated polyether group, particularly preferably a fluorinated polyether group.

The organic group can also be unsaturated and contain one or a plurality of double and/or triple bonds. The organic group can also include aromatic groups.

The hydrophobic coating can also include waxes, synthetic resins, or silicones, preferably halogenated, particularly preferably fluorinated silicones.

The hydrophobic coating can also include mixtures of various organosilanes, silicones, waxes, and/or synthetic resins.

The hydrophobic coating can be covalently or electrostatically bonded to the surface of the substrate.

The layer thickness of the hydrophobic coating is preferably from 0.5 nm to 50 nm, particularly preferably from 1 nm to 5 nm, most particularly preferably from 1.2 nm to 4 nm, and in particular from 1.5 nm to 3 nm. This is particularly advantageous with regard to the hydrophobic properties and the mechanical stability of the coating.

One or a plurality of additional coatings can be arranged between the substrate and the hydrophobic coating.

In a preferred embodiment of the invention, a diffusion barrier layer against alkali ions is arranged between the substrate and the hydrophobic coating. This prevents the diffusion of alkali ions, for example, sodium or potassium ions, out of the substrate onto the surface of the substrate. The deposition of alkali ions onto the surface of substrate can result in an increase in the surface conductivity of the substrate and thus in an increase in the electrical field between the module frame and the photovoltaic layer structure. Thus, advantageously, a further reduction of the electrical field is achieved by means of the diffusion barrier layer. The diffusion barrier layer contains, for example, at least silicon nitride, silicon oxynitride, silicon oxide, aluminum nitride, or aluminum oxynitride. The diffusion barrier layer preferably contains at least silicon nitride. This is particularly advantageous with regard to the thermal and chemical stability of the coating and the capability of the coating to prevent the diffusion of alkali ions. The surface conductivity of the substrate is further reduced by the high specific resistance of the silicon nitride. The diffusion barrier layer can also contain admixtures at least of a metal, for example, aluminum or boron.

The layer thickness of the diffusion barrier layer is preferably from 3 nm to 300 nm, particularly preferably from 10 nm to 200 nm, and most particularly preferably from 20 nm to 100 nm. Particularly good results are obtained therewith.

The cover sheet and substrate are preferably made of tempered, partially tempered, or non-tempered glass, in particular float glass. The cover sheet contains in particular hardened or non-hardened low-iron soda-lime glass with high permeability to sunlight. The invention is particularly advantageous when the substrate contains 0.1 wt.-% to 20 wt.-%, preferably 10 wt.-% to 16 wt.-% of alkali elements, particularly preferably Na₂O. Other insulating materials with adequate strength as well as inert behavior relative to the process steps performed can also be used for the substrate. The cover sheet and substrate preferably have thicknesses from 1.5 mm to 10 mm. The area of the pane can be 100 cm² up to 18 m², preferably 0.5 m² to 3 m². The thin-film photovoltaic modules can be flat or curved.

The photovoltaic layer structure comprises at least one photovoltaically active absorber layer between a front electrode layer and a rear electrode layer. The rear electrode layer is arranged between the substrate and the absorber layer.

The photovoltaically active absorber layer includes at least one p-conductive semiconductor layer. In an advantageous embodiment of the invention, the p-conductive semiconductor layer contains amorphous, micromorphous, or polycrystalline silicon, cadmium telluride (CdTe), gallium arsenide (GaAs), an organic semiconductor, or a p-conductive chalcopyrite semiconductor, such as a compound of the group copper indium sulfur/selenium (CIS), for example, copper indium diselenide (CuInSe₂), or a compound of the group copper indium gallium sulfur/selenium (GIGS), for example, Cu(InGa)(SSe)₂. The absorber layer can be doped with metals, preferably sodium. The photovoltaically active absorber layer preferably has a layer thickness from 500 nm to 5 μm, particularly preferably from 1 μm to 3 μm.

In an advantageous embodiment of the invention, the rear electrode layer contains at least one metal, preferably molybdenum, titanium, tungsten, nickel, titanium, chromium and/or tantalum. The rear electrode layer preferably has a layer thickness from 300 nm to 600 nm. The rear electrode layer can comprise a layer stack of different individual layers. Preferably, the layer stack contains a diffusion barrier layer made, for example, of silicon nitride, to prevent diffusion of, for example, sodium out of the substrate into the photovoltaically active absorber layer.

The front electrode layer is transparent in the spectral range in which the semiconductor layer is sensitive. In an advantageous embodiment of the invention, the front electrode layer contains an n-conductive semiconductor, preferably aluminum-doped zinc oxide or indium tin oxide. The front electrode layer preferably has a layer thickness from 500 nm to 2 μm.

The electrode layers can also contain silver, gold, copper, nickel, chromium, tungsten, tin oxide, silicon dioxide, silicon nitride, and/or combinations as well as mixtures thereof.

A buffer layer can be arranged between the front electrode layer and the absorber layer. The buffer layer can effect an electronic adaptation between the absorber material and the front electrode layer. The buffer layer contains, for example, a cadmium-sulfur compound and/or intrinsic zinc oxide. The buffer layer preferably has a layer thickness from 1 nm to 50 nm, particularly preferably from 5 nm to 30 nm.

The photovoltaic layer structure is preferably a monolithically integrated electrical serial circuit. The photovoltaic structure is divided into individual photovoltaically active regions, so-called “solar cells”, that are connected to one another in series via a region of the rear electrode layer.

The photovoltaic layer structure is preferably decoated peripherally on the edge of the substrate with a width of preferably 5 mm to 20 mm, particularly preferably from 10 mm to 15 mm, in order to be protected on the edge against the entry of moisture or shadowing by mounting elements.

A peripheral edge region of the rear electrode layer is preferably not coated with the photovoltaically active absorber layer. The width of the edge region of the rear electrode layer not coated by the absorber layer is preferably from 5 mm to 30 mm, for example, roughly 15 mm. This region preferably serves for the electrical contacting of the rear electrode with, for example, a foil conductor.

The cover sheet is areally bonded via its rear side with at least one intermediate layer to the front side of the substrate. Since the photovoltaic layer structure is arranged extensively on the front side of the substrate, the bonding between the substrate and the intermediate layer takes place extensively via the photovoltaic layer structure. The intermediate layer preferably contains thermoplastic plastics, such as polyvinyl butyral (PVB) and/or ethylene vinyl acetate (EVA) or a plurality of layers thereof, preferably with thicknesses from 0.3 mm to 0.9 mm. The intermediate layer can also contain polyurethane (PU), polypropylene (PP), polyacrylate, polyethylene (PE), polycarbonate (PC), polymethyl methacrylate, polyvinyl chloride, polyacetate resin, casting resins, acrylates, fluorinated ethylene propylenes, polyvinyl fluoride, ethylene tetrafluoroethylene, copolymers, and/or mixtures thereof.

In an advantageous embodiment of the invention, electrically conductive mounting means are applied on the thin-film photovoltaic module, preferably on the outer edges of the cover sheet and substrate.

In another advantageous embodiment of the invention, the electrically conductive mounting means at least partially surround the thin-film photovoltaic module on the outer edges of the cover sheet and the substrate. Preferably, electrically conductive mounting means are designed as a peripheral frame along the outer edge of the thin-film photovoltaic module.

The electrically conductive mounting means can, however, also preferably be implemented as a continuous frame, a surrounding frame, or as metal fittings. The mounting of the thin-film photovoltaic module on, for example, racks takes place via screwing, clamping, and/or gluing of the mounting elements. The electrical potential of the mounting means usually corresponds to the ground potential of a reference system, preferably the potential of the ground.

The object of the invention is further accomplished by a method for producing a thin-film photovoltaic module with hydrophobic rear-side coating, wherein at least

a) a photovoltaic layer structure is applied on the front side of a substrate,
b) the front side of the substrate is bonded to the rear side of a cover sheet via an intermediate layer under the action of heat, vacuum, and/or pressure, and
c) a hydrophobic coating is applied on the rear side of the substrate.

The hydrophobic coating is applied according to the invention after the bonding of the cover sheet, substrate, and photovoltaic layer structure to form the photovoltaic module. Thus, damaging of the hydrophobic coating through especially thermal and/or mechanical loads during the production of the photovoltaic module can advantageously be avoided.

The hydrophobic coating is preferably applied as a solution on the rear side of the substrate. The solution preferably contains at least one organosilane. The concentration of the organosilane in the solution is preferably from 0.05 wt.-% to 5 wt.-%, particularly preferably from 1 wt.-% to 3 wt.-%. This is particularly advantageous with regard to the formation of a homogeneous coating.

The organosilane preferably has the general chemical formula

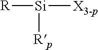

X is a hydroxy group or a hydrolyzable functional group, preferably an alkoxy group, particularly preferably a methoxy or ethoxy group, or a halogen atom, particularly preferably a chlorine atom. In the method according to the invention, any hydrolyzable functional group can react with water with elimination of H—X to form a hydroxy group. The organosilane can react via the hydroxy groups with reactive groups on the surface of the substrate, preferably hydroxy groups with elimination of water and thus form a covalent bond on the substrate. Alternatively, the organosilane can react without prior hydrolysis with the hydroxy groups on the surface of the substrate with elimination of H—X.

p is a whole number from 0 to 2, preferably p=0. This is particularly advantageous with regard to the stability of the bonding of the organosilane to the substrate.

In an advantageous embodiment of the invention, the organosilane is at least an alkylsilane. R can be a linear alkyl group. The alkylsilane has the general chemical formula:

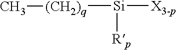

q is a whole number, preferably from 1 to 20, particularly preferably from 7 to 15. This is particularly advantageous with regard to the hydrophobic properties of the coating and the reactivity of the alkylsilane.

Alternatively, R can contain a branched alkyl group, a cycloalkyl group, an alkenyl group, an alkinyl group, or an aryl group.

In another advantageous embodiment of the invention, the organosilane is at least a halogenated, preferably fluorinated alkylsilane. Particularly preferably, R contains at least one perfluorinated alkyl group on the chain end facing away from the silicon atom. An especially advantageous hydrophobic property and chemical resistance of the coating is achieved by means of the fluorine atom. In addition, the coating is also oleophobic. The fluorinated alkylsilane preferably has the general chemical formula:

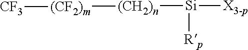

n is a whole number, preferably from 1 to 5. m is a whole number, preferably from 0 to 15. Particularly preferably, m is at least twice as large as n. This is particularly advantageous with regard to the hydrophobic properties and the chemical resistance of the coating and the reactivity of the fluorinated alkylsilane.

In another advantageous embodiment of the invention, R contains a polyether group, preferably a halogenated, particularly preferably a fluorinated polyether group. The polyether silane preferably has the general chemical formula:

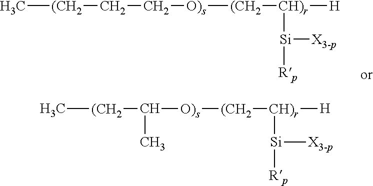

The fluorinated polyether silane preferably has the general chemical formula:

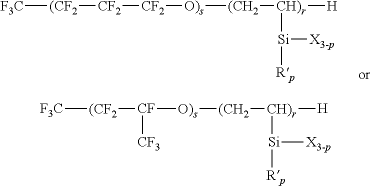

r is a whole number, preferably from 1 to 3, particularly preferably r=1. s is a whole number, preferably from 2 to 30. Particularly good results are obtained therewith.

The hydrophobic coating solution can, alternatively, contain waxes, synthetic resins, or silicones, preferably halogenated, particularly preferably fluorinated silicones.

The hydrophobic coating solution can also contain mixtures of different organosilanes, silicones, waxes, and/or synthetic resins.

R′ ist preferably an alkyl group or hydrogen.

The solvent preferably contains at least one alcohol, for example, ethanol or isopropanol. The solvent particularly preferably contains a mixture of at least one alcohol and water. The water serves for the hydrolysis of the hydrolyzable groups of the organosilane. That is particularly advantageous with regard to the stability and the speed of the bonding of the hydrophobic coating to the surface of the substrate. The fraction of the water in the solvent is preferably from 3 vol.-% to 20 vol.-%. That is particularly advantageous with regard to an effective activation of the organosilane through hydrolysis and avoidance of homopolymerization reactions of the organosilane.

In an advantageous embodiment of the invention, the solution also contains a catalyst. The catalyst accelerates the hydrolysis of the hydrolyzable groups of the organosilane. The catalyst preferably contains a Bronsted acid, for example, hydrochloric acid or acetic acid, or a Bronsted base, for example, sodium hydroxide. The solution preferably contains 0.005 wt.-% to 20 wt.-%, particularly preferably from 5 wt.-% to 15 wt.-% catalyst. Particularly good results are obtained therewith.

The solution can, for example, be applied by spraying or brushing. Alternatively, the substrate can be dipped in the solution. The temperature of the substrate at the time of application of the solution is preferably from 20° C. to 300° C. That is particularly advantageous with regard to the speed of the bonding of the hydrophobic coating and substrate and to the avoidance of thermal damage to the components of the hydrophobic coating. The substrate can also be heated to a temperature from 20° C. to 300° C. after the application of the solution.

In an advantageous embodiment of the invention, an adhesion promoter is applied on the rear side of the substrate before the application of the hydrophobic coating. The adhesion promoter preferably contains at least one silane, whereby the silicon atom is substituted by at least two hydroxy groups and/or hydrolyzable groups, for example, alkoxy groups or halogen atoms. The silicon atom is particularly preferably substituted by four hydroxy groups and/or hydrolyzable groups. This silane can be bonded to the surface of the substrate, on the one hand, via the hydroxy groups or the hydrolyzable groups and, on the other, to the hydrophobic coating, in particular by covalent chemical bonding. The particular advantage resides in a durably stable bonding of the hydrophobic coating to the substrate. The adhesion promoter is preferably applied in a solvent, for example, by spraying, brushing, or dipping of the substrate into the solution. The solution preferably contains from 0.001 wt.-% to 5 wt.-% of the adhesion promoter. Particularly good results are obtained therewith.

In another advantageous embodiment of the invention, a diffusion barrier layer against alkali ions is applied on the rear side of the substrate, before the hydrophobic coating is applied. The diffusion barrier layer can be applied on the front side of the substrate before or after the application of the photovoltaic layer structure. The diffusion barrier layer can be applied before or after the bonding of the cover sheet and substrate.

The diffusion barrier layer contains, for example, silicon oxynitride, silicon oxide, aluminum nitride, aluminum oxynitride, preferably silicon nitride. The diffusion barrier layer is applied on the substrate by cathode sputtering, for example.

The individual layers of the photovoltaic layer structure are preferably applied on the surface by cathode sputtering, vapor deposition, or chemical vapor deposition (CVD).

In a preferred embodiment of the invention, the photovoltaic layer structure is divided into individual photovoltaically active regions, so-called “solar cells”. The division is accomplished by incisions into individual layers or individual groups of layers of the layer structure after their application using a suitable structuring technology such as laser writing and machining, for example, by cutting or scoring.

In a preferred embodiment, the edge region of the substrate is decoated. The decoating of the edge region is accomplished, for example, by means of laser ablation, plasma etching, or mechanical processes. Alternatively, masking techniques can be used.

Preferably, the rear and/or the front electrode layer is electrically conductively connected to, for example, a foil conductor for electrical contacting after the application of the layer structure on the substrate and before the bonding of the cover sheet and substrate. The electrically conductive connection is accomplished, for example, by welding, bonding, soldering, clamping, or gluing with an electrically conductive adhesive. The connection of the foil conductor to the rear and/or the front electrode layer can also be accomplished via a busbar.

For the bonding of the cover sheet and the substrate to an intermediate layer, the methods familiar to the person skilled in the art with and without prior production of a pre-laminate can be used. For example, so-called “autoclave methods” can be performed at an elevated pressure of roughly 10 bar to 15 bar and in temperatures from 130° C. to 145° C. over roughly 2 hours. Vacuum bag or vacuum ring methods known per se operate, for example, at roughly 200 mbar and 130° C. to 145° C.

Preferably, the cover sheet and substrate can be pressed with an intermediate layer in a calender between at least one pair of rollers to form a photovoltaic module according to the invention. Systems of this type are known for production of a laminated glazings and normally have at least one heating tunnel upstream from a pressing unit. The temperature during the pressing procedure is, for example, from 40° C. to 150° C. Combinations of calendering and autoclaving methods have proved particularly valuable in practice.

Alternatively, vacuum laminators are used for producing the photovoltaic modules according to the invention. These consist of one or a plurality of a heatable and evacuable chambers in which the cover sheet and substrate can be laminated within, for example, roughly 60 minutes at reduced pressures from 0.01 mbar to 800 mbar and temperatures from 80° C. to 170° C.

The thin-film photovoltaic module is preferably used in a series-connected circuit of photovoltaic modules with a negative electrical potential to the earth ground of at least −100 V and particularly preferably at least −600 V.

The invention further includes the use of the hydrophobic coating on the surface of thin-film photovoltaic modules turned away from the light entry to avoid the formation of a continuous film of water and thus to reduce surface conductivity.

The invention is explained in detail with reference to drawings and exemplary embodiments. The drawings are a schematic representation and not true to scale. The drawings in no way restrict the invention. They depict:

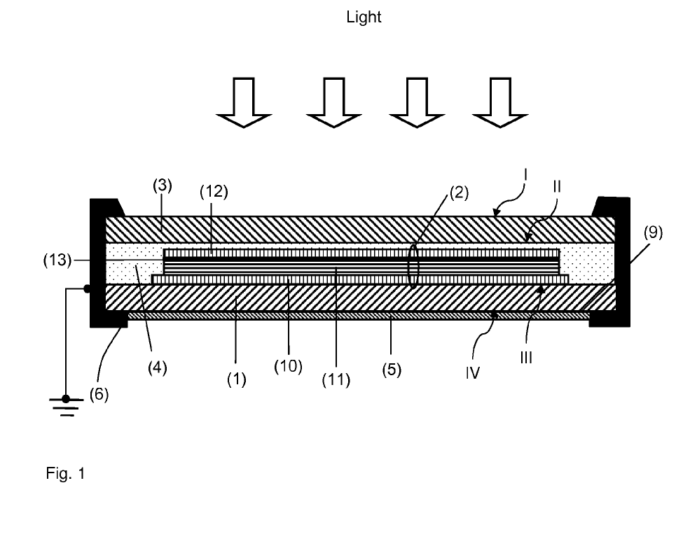

FIG. 1 a cross-section through a thin-film photovoltaic module with hydrophobic rear-side coating according to the invention.

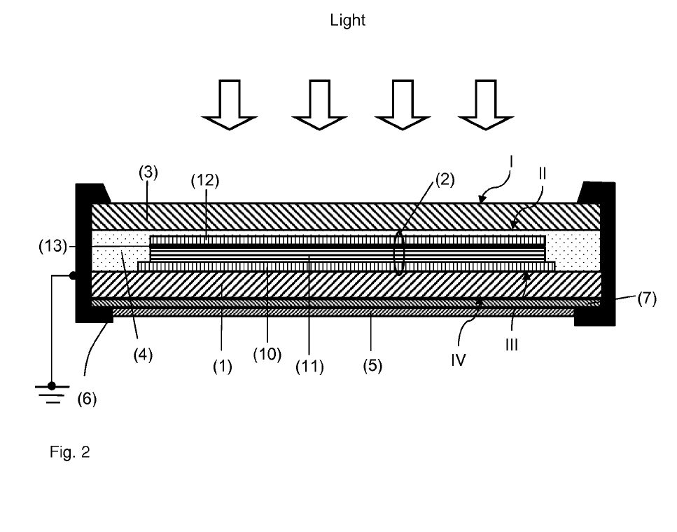

FIG. 2 a cross-section through an alternative embodiment of the thin-film photovoltaic module with hydrophobic rear-side coating according to the invention, and

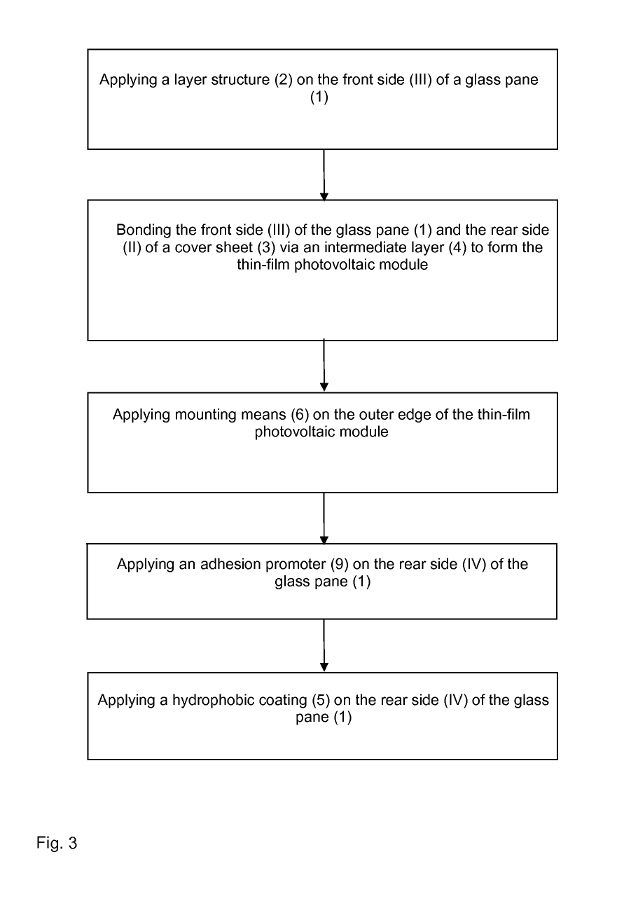

FIG. 3 a detailed flow chart of the method according to the invention.

FIG. 1 depicts a section through a thin-film photovoltaic module with hydrophobic rear-side coating 5 according to the invention. The thin-film photovoltaic module comprises an electrically insulating substrate 1 made of soda-lime glass with a sodium oxide content of 12 wt.-%. A photovoltaic layer structure 2 is applied on the front side (III) of the substrate 1.

The photovoltaic layer structure 2 comprises a rear electrode layer 10 that contains molybdenum and has a layer thickness of roughly 300 nm arranged on the front side (III) of the substrate 1. The photovoltaic layer structure 2 further contains a photovoltaically active absorber layer 11, which contains sodium-doped Cu(InGa)(SSe)₂ and has a layer thickness of roughly 2 μm. The photovoltaic layer structure 2 further contains a front electrode layer 12, which contains aluminum-doped zinc oxide (AZO) and has a layer thickness of roughly 1 μm. Between the front electrode layer 12 and the absorber layer 11, a buffer layer 13 is deposited, which contains an individual layer of cadmium sulfide (CdS) and an individual layer of intrinsic zinc oxide (i-ZnO). The photovoltaic layer structure 2 is divided using methods known per se for producing a thin-film photovoltaic module in individual photovoltaically active zones, so-called “solar cells”, that are series connected to each other via a region of the rear electrode layer 10. The photovoltaic layer structure 2 is abrasively decoated mechanically in the edge region of the substrate 1 with a width of 15 mm.

The substrate 1 and the photovoltaic layer structure 2 are bonded to the rear side (II) of the cover sheet 3 via the intermediate layer 4. The cover sheet 3 is transparent to sunlight and contains hardened, extra-white glass with low iron content. The front side (I) of the cover sheet 3 faces the light incidence. The cover sheet 3 has an area of 1.6 m×0.7 m. The intermediate layer 4 contains polyvinyl butyral (PVB) and has a layer thickness of 0.76 mm. The outer edge of the thin-film photovoltaic module is framed by an aluminum frame as an electrically conductive mounting 6. The bracketing of the mounting frame 6 is accomplished with a depth of 5 mm on the surface of substrate 1 and cover sheet 3.

A hydrophobic coating 5 is applied on the rear side (IV) of the substrate 1 turned away from the photovoltaic layer structure 2. The hydrophobic coating 5 covers the entire region of the rear side (IV) of the substrate 1 that is not covered by the electrically conductive mounting 6. The hydrophobic coating 5 contains a fluorinated alkylsilane that was applied to the substrate 1 as F₃C(CF₂)₇(CH₂)₂SiCl₃. The hydrophobic coating 5 has a layer thickness of 1.5 nm. The hydrophobic coating 5 is bonded to the surface (IV) of the substrate 1 via an adhesion promoter 9. The adhesion promoter 9 was applied to the substrate 1 as alkoxy silane with the chemical formula Si(OCH₃)₄.

The hydrophobic coating 5 enlarges the contact angle for water relative to the surface (IV) of the substrate 1. This reduces the wetting of the surface (IV) of the substrate 1 with water as a result of precipitation or due to condensed atmospheric moisture and, in particular, prevents the formation of a continuous film of water on the surface (IV) of the substrate 1. Thus, a reduction of the surface conductivity of the substrate 1 is obtained. The lower surface conductivity of the substrate 1 results in a lower electrical field strength between the electrically conductive mounting 6 and the photovoltaic layer structure 2. The migration of alkali ions out of the substrate 1 into the photovoltaic layer structure 2 caused by the electrical field can thus be reduced. This advantageously reduces the corrosion of the photovoltaic layer structure 2. Moreover, the hydrophobic coating 2 reduces the risk of entry of moisture into the thin-film photovoltaic module.

FIG. 2 depicts a section through an alternative embodiment of the thin-film photovoltaic module with hydrophobic rear-side coating 5 according to the invention. A diffusion barrier layer 7 against alkali ions is arranged between the hydrophobic rear-side coating 5 and the rear side (IV) of the substrate 1. The diffusion barrier layer 7 contains silicon nitride and has a layer thickness of 50 nm. The diffusion barrier layer 7 prevents the diffusion of alkali ions out of the substrate 1 to the surface (IV) of the substrate 1. This prevents the deposition of alkali ions on the surface (IV) of the substrate 1 and further reduces the surface conductivity of the substrate 1.

FIG. 3 depicts, by way of example, the method for producing a thin-film photovoltaic module with hydrophobic rear-side coating 5 according to the invention.

### EXAMPLE 1

Test specimens of a thin-film photovoltaic module were made with the substrate 1, the photovoltaic layer structure 2, the cover sheet 3, the intermediate layer 4, the electrically conductive mounting 6, and the hydrophobic coating 5. The substrate 1 and the cover sheet 3 were made of soda-lime glass and had a length and width of 30 cm and a thickness of 2.9 mm. The photovoltaic layer structure 2 comprised, in succession, a rear electrode layer 10, a photovoltaically active absorber layer 11, a buffer layer 13, and a front electrode layer 12. The rear electrode layer 10 contained molybdenum and had a layer thickness of 300 nm. The photovoltaically active absorber layer 11 contained sodium-doped Cu(InGa)(SSe)₂ and had a layer thickness of 2 μm. The buffer layer 13 contained cadmium sulfide (CdS) and had a thickness of roughly 20 nm. The front electrode layer 12 contained aluminum-doped zinc oxide (AZO) and had a layer thickness of 1 μm. The photovoltaic layer structure 2 was decoated in the edge region of the substrate 1 with a width of 15 mm and had a length and width of 27 cm. The photovoltaic layer structure 2 was not divided into individual photovoltaically active regions and thus formed a single solar cell. The photovoltaic layer structure 2 was bonded via the rear electrode layer 10 to the front side (III) of the substrate 1. The rear side (II) of the cover sheet 3 was bonded via the intermediate layer 4 to the front side (III) of the substrate 1. The intermediate layer 4 contained polyvinyl butyral (PVB) and had a layer thickness of 0.76 mm. The outer edge of the thin-film photovoltaic module was framed by an electrically conductive mounting 6 made of aluminum.

A hydrophobic coating 5 was applied on the rear side (IV) of the substrate 1. The composition and the layer thickness of the hydrophobic coating 5 are presented in Table 1. Before the application of the hydrophobic coating 5, an adhesion promoter 9 that contained the alkoxy silane Si(OCH₃)₄ was applied on the rear side (IV) of the substrate 1.

An electrical potential of −1000 V compared to the grounded electrically conductive mounting 6 was applied to the photovoltaic layer structure 2. Due to the hydrophobic coating 5, no continuous film of water was able to form on the rear side (IV) of the substrate 1 as a result of the condensation of moisture in the test cell.

The beginning of obvious corrosion of the photovoltaic layer structure 2 was observed after a test period of 220 hours. After a test period of 500 hours, it was observed that the photovoltaic layer structure 2 was corroded or delaminated over roughly 25% of its area. The results are presented in Table 2.

### EXAMPLE 2

Example 2 was carried out the same as Example 1. In addition, a diffusion barrier layer 7 against alkali ions was applied between substrate 1 and hydrophobic coating 5. The compositions and layer thicknesses of the hydrophobic coating 5 and the diffusion barrier layer 7 are presented in Table 1. By means of the diffusion barrier layer 7, it was possible to reduce the deposition of alkali ions on the rear side (IV) of the substrate 1 during the production process of the thin-film photovoltaic module. It was thus possible to further reduce the surface conductivity of the substrate 1.

Compared to Example 1, it was possible to observe a later onset of corrosion of the photovoltaic layer structure 2. After a test period of 500 hours, a smaller fraction of the photovoltaic layer structure 2 was corroded or delaminated. The results are presented in Table 2.

### Comparative Example

The comparative example was carried out the same as Example 1. In contrast to Example 1, no hydrophobic coating 5 was applied on the rear side (IV) of the substrate 1. Thus it was not possible to prevent the formation of a continuous film of water on the rear side (IV) of the substrate 1 as a result of condensed moisture in the test cell. Consequently, the substrate 1 had a higher surface conductivity than in the examples according to the invention.

Compared to the examples according to the invention, in the comparative example, an earlier onset of corrosion of the photovoltaic layer structure 2 was observed. After a test period of 500 hours, a larger fraction of the photovoltaic layer structure 2 was corroded or delaminated. The results are presented in Table 2.

TABLE 1

| | | Layer Thickness | | |
|---|---|---|---|---|
| | | | Exam- | Comparative |
| Component | Material | Example 1 | ple 2 | Example |
| Hydrophobic | fluorinated alkylsilane, | 1.5 nm | 1.5 nm | (not |
| coating 5 | starting condition: | | | present) |
| | F₃C(CF₂)₇(CH₂)₂SiCl₃ | | | |
| Diffusion | silicon nitride | (not | 100 nm | (not |
| barrier | | present) | | present) |
| layer 7 | | | | |

TABLE 2

| | | Corroded/delaminated fraction of the |
|---|---|---|
| | Start of corrosion/ | area of the photovoltaic layer structure 2 |
| | Delamination | after 500 h |
| Example 1 | 220 h | 25% |
| Example 2 | 400 h | 10% |
| Comparative | 100 h | 45% |
| example | | |

It was demonstrated that thin-film photovoltaic modules with hydrophobic rear-side coating 5 according to the invention, and preferably with a diffusion barrier layer 7, had better stability against corrosion than known thin-film photovoltaic modules.

This result was unexpected and surprising for the person skilled in the art.

### LIST OF REFERENCE CHARACTERS

(1) substrate
(2) photovoltaic layer structure
(3) cover sheet
(4) intermediate layer
(5) hydrophobic coating
(6) electrically conductive mounting means
(7) diffusion barrier layer
(9) adhesion promoter
(10) rear electrode layer
(11) absorber layer
(12) front electrode layer
(13) buffer layer
I front side of the cover sheet 3
II rear side of the cover sheet 3
III front side of the substrate 1
IV rear side of the substrate 1

1. A thin-film photovoltaic module with hydrophobic rear-side coating, comprising at least:
a substrate, wherein at least one hydrophobic coating is arranged on a rear side of the substrate;
a photovoltaic layer structure on a front side of the substrate; and
a cover sheet areally bonded via a rear side of said cover sheet with at least one intermediate layer to the front side of the substrate.

2. The thin-film photovoltaic module according to claim 1, wherein the at least one hydrophobic coating contains at least one alkylsilane, preferably a fluorinated alkylsilane.

3. The thin-film photovoltaic module according to claim 1, wherein the at least one hydrophobic coating has a layer thickness from 0.5 nm to 50 nm.

4. The thin-film photovoltaic module according to claim 1, wherein a diffusion barrier layer against alkali ions is arranged between the at least one hydrophobic coating and the substrate.

5. The thin-film photovoltaic module according to claim 4, wherein the diffusion barrier layer contains at least silicon nitride, silicon oxynitride, silicon oxide, aluminum nitride, and/or aluminum oxynitride and has a layer thickness from preferably 3 nm to 300 nm.

6. The thin-film photovoltaic module according to claim 1, wherein the substrate contains at least soda-lime glass, preferably with a thickness from 1.5 mm to 10 mm, and the fraction of alkali elements is preferably from 0.1 wt.-% to 20 wt.-%.

7. The thin-film photovoltaic module according to claim 1, wherein the photovoltaic layer structure has at least one photovoltaically active absorber layer between a front electrode layer and a rear electrode layer, and the rear electrode layer contains at least one metal, preferably molybdenum, titanium nitride compounds, or tantalum nitride compounds, and the front electrode layer contains at least one n-conductive semiconductor, preferably aluminum-doped zinc oxide or indium tin oxide, and the photovoltaically active absorber layer contains at least amorphous, micromorphous, or polycrystalline silicon, cadmium telluride (CdTe), gallium arsenide (GaAs), or copper indium (gallium) sulfur/selenium (CI(G)S).

8. A method for producing a thin-film photovoltaic module with hydrophobic rear-side coating, comprising:
(a) applying a photovoltaic layer structure on a front side of a substrate;
(b) bonding the front side of the substrate to a rear side of a cover sheet via an intermediate layer under action of heat, vacuum, and/or pressure, and
(c) applying a hydrophobic coating on a rear side of the substrate.

9. The method according to claim 8, wherein the hydrophobic coating is applied in step (c) from a solution that contains at least 0.05 wt.-% to 5 wt.-% of an alkylsilane, preferably a fluorinated alkylsilane, with one, two, or three hydrolyzable substituents on the silicon atom, preferably alkoxy groups or halogen atoms and a solvent.

10. The method according to claim 9, wherein the solvent contains at least a mixture of an alcohol and water, and the fraction of water in the solvent mixture is from 3 vol.-% to 20 vol.-%.

11. The method according to claim 9, wherein the solution contains 0.005 wt.-% to 20 wt.-% of a Bronsted acid or of a Bronsted base as a catalyst.

12. The method according to claim 8, wherein, before step (c) an adhesion promoter is applied on the rear side of the substrate and the adhesion promoter preferably contains at least tetrahydroxy silane, a tetra-alkoxy silane, and/or a tetrahalogen silane.

13. The method according to claim 8, wherein, before step (a) or before step (b) or before step (c), a diffusion barrier layer is applied on the rear side of the substrate.

14. A method comprising:
using the thin-film photovoltaic module according to claim 1 with a negative electrical potential to earth ground of at least −100 V and preferably at least −600 V.

15. A method comprising:
using the at least one hydrophobic coating on a surface of the thin-film photovoltaic module turned away from an entry of light according to claim 1.

16. The thin-film photovoltaic module according to claim 1, wherein the at least one hydrophobic coating has a layer thickness from 1 nm to 5 nm.

17. The thin-film photovoltaic module according to claim 5, wherein the diffusion barrier layer has a thickness from 10 nm to 200 nm.

18. The thin-film photovoltaic module according to claim 5, wherein the diffusion barrier layer has a thickness from 20 nm to 100 nm.

19. The thin-film photovoltaic module according to claim 6, wherein the fraction of alkali elements is preferably from 10 wt.-% to 16 wt.-%.
